(19) United States
(12) Patent Application Publication
(10) Pub. No.: US 2025/0157869 A1
(43) Pub. Date: May 15, 2025

(54) ENCAPSULANT WITH ORGANIC CONSTITUENT AND INORGANIC CONSTITUENT HAVING ADJUSTED RELATIVE DIELECTRIC CONSTANT

(71) Applicant: Infineon Technologies AG, Neubiberg (DE)

(72) Inventors: Patrick SCHRÖDL, Wald (DE); Michael BAUER, Nittendorf (DE); Timo BOHNENBERGER, Neutraubling (DE); Stefan PELTIES, Regensburg (DE)

(73) Assignee: Infineon Technologies AG, Neubiberg (DE)

(21) Appl. No.: 18/899,124

(22) Filed: Sep. 27, 2024

(30) Foreign Application Priority Data
Nov. 13, 2023 (DE) 10 2023 131 556.0

(51) Int. Cl. H01L 23/29; C09D 7/61

(52) U.S. Cl. CPC H01L 23/295; C09D 7/61

(57) ABSTRACT

An encapsulant for an electronic package is disclosed. In one example, the encapsulant comprises at least one organic constituent, and at least one inorganic constituent. A difference between the relative dielectric constant of the at least one organic constituent and the relative dielectric constant of the at least one inorganic constituent divided by the relative dielectric constant of the at least one organic constituent has an absolute value of not more than 0.2.

### CROSS-REFERENCE TO RELATED APPLICATION

This Utility Patent Application claims priority to German Patent Application No. 10 2023 131 556.0 filed Nov. 13, 2023, which is incorporated herein by reference.

### BACKGROUND

### Technical Field

Various embodiments relate generally to an encapsulant, a package, and a manufacturing method.

### Description of the Related Art

A conventional package may comprise a semiconductor component mounted on a carrier such as a leadframe structure, may be electrically connected by a bond wire extending from the semiconductor component to the carrier, and may be molded using a mold compound as an encapsulant.

Electric reliability of such a package may be an issue.

### SUMMARY

There may be a need for a package with high electric reliability.

According to an exemplary embodiment, an encapsulant for an electronic package is provided, wherein the encapsulant comprises at least one organic constituent, and at least one inorganic constituent, wherein a difference between the relative dielectric constant of the at least one organic constituent and the relative dielectric constant of the at least one inorganic constituent divided by the relative dielectric constant of the at least one organic constituent has an absolute value of not more than 0.2.

According to another exemplary embodiment, a package is provided which comprises a carrier, an electronic component mounted on the carrier, and an encapsulant having the above mentioned features at least partially encapsulating the electronic component and the carrier.

According to still another exemplary embodiment, a method of manufacturing an encapsulant for an electronic package is provided, wherein the method comprises defining at least one organic constituent and at least one inorganic constituent of the encapsulant, determining a chemical modification to be applied to the defined at least one organic constituent to reduce a difference between the relative dielectric constant of the at least one organic constituent and the relative dielectric constant of the at least one inorganic constituent by the chemical modification, and manufacturing the encapsulant based on the defined at least one inorganic constituent and based on the at least one organic constituent with the determined chemical modification.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates an encapsulant according to an exemplary embodiment.

FIG. 2 illustrates a flowchart of a method of manufacturing an encapsulant according to an exemplary embodiment.

FIG. 3 to FIG. 21 show chemical compounds which may be used for constructing an encapsulant according to exemplary embodiments.

FIG. 22 to FIG. 24 show diagrams used for explaining effects of exemplary embodiments compared to conventional approaches.

FIG. 25 illustrates a cross-sectional view of a package according to an exemplary embodiment.

FIG. 26 illustrates a cross-sectional view of a package according to another exemplary embodiment.

### DETAILED DESCRIPTION

There may be a need for a package with high electric reliability.

According to an exemplary embodiment, an encapsulant for an electronic package is provided, wherein the encapsulant comprises at least one organic constituent, and at least one inorganic constituent, wherein a difference between the relative dielectric constant of the at least one organic constituent and the relative dielectric constant of the at least one inorganic constituent divided by the relative dielectric constant of the at least one organic constituent has an absolute value of not more than 0.2.

According to another exemplary embodiment, a package is provided which comprises a carrier, an electronic component mounted on the carrier, and an encapsulant having the above mentioned features at least partially encapsulating the electronic component and the carrier.

According to still another exemplary embodiment, a method of manufacturing an encapsulant for an electronic package is provided, wherein the method comprises defining at least one organic constituent and at least one inorganic constituent of the encapsulant, determining a chemical modification to be applied to the defined at least one organic constituent to reduce a difference between the relative dielectric constant of the at least one organic constituent and the relative dielectric constant of the at least one inorganic constituent by the chemical modification, and manufacturing the encapsulant based on the defined at least one inorganic constituent and based on the at least one organic constituent with the determined chemical modification.

According to an exemplary embodiment, an encapsulant (for example a mold compound) for encapsulating an electronic package (in particular for encapsulating an electronic component mounted on a carrier) is provided which offers an excellent electric reliability. Said encapsulant may be composed of one or more organic constituents and one or more inorganic constituents. Usually, organic and inorganic constituents of an encapsulant may have significantly different values of the relative dielectric constant or relative permittivity (εᵣ), which may lead to local electric fields in the dielectric encapsulant and finally to material decomposition and limited lifetime stability of the encapsulant and a package having such an encapsulant. Advantageously, an exemplary embodiment provides an encapsulant with organic and inorganic constituents being configured so that a difference between the relative dielectric constant of the at least one organic constituent and the relative dielectric constant of the at least one inorganic constituent divided by the relative dielectric constant of the at least one organic constituent has an absolute value of not more than 0.2. To put it shortly, organic and inorganic constituents of an encapsulant may be provided with better matching values of the relative dielectric constant with a relative deviation of not more than 20% or within a range of ±0.2 in accordance with the above-mentioned definition. By such a selection or adaptation of the dielectric constant of inorganic and organic components of an encapsulant, the electric field strength may be significantly reduced. As a result, lifetime stability of the encapsulant may be increased and material decomposition of the encapsulant can be suppressed. Further advantageously, reliability failure of a package with encapsulated electronic component(s) may be provided when implementing an electrically insulating encapsulant with adapted gr-values of its organic and inorganic constituents.

In order to adjust matching values of the relative dielectric constant of organic and inorganic constituents of an encapsulant, it may be possible to virtually define one or more organic constituents and one or more inorganic constituents of an encapsulant to be developed. Furthermore, a chemical modification to be applied to said one or more defined organic constituents may be determined which would allow to reduce (preferably to not more than ±20%) a difference between the relative dielectric constant of the modified at least one organic constituent and the relative dielectric constant of the at least one inorganic constituent by the envisaged chemical modification. If a chemical modification is found (for instance based on a numerical, theoretical and/or empirical evaluation) which would meet said criterion in terms of relative dielectric constants, the encapsulant may be subsequently manufactured according to the previously derived recipe, i.e. based on the defined at least one inorganic constituent and based on the at least one organic constituent with the determined Fr-mismatch reducing chemical modification. By such an architecture, an encapsulant may be developed and manufactured which has an excellent electric reliability.

### Description of Further Exemplary Embodiments

In the following, further exemplary embodiments of the encapsulant, the package, and the method will be explained.

In the context of the present application, the term “encapsulant” may particularly denote a material, structure or member surrounding or intended for surrounding at least part of an electronic component and at least part of a carrier of a package. In this context, an encapsulant may provide mechanical protection and electrical insulation, and optionally a contribution to heat removal during operation. In particular, said encapsulant may be electrically insulating, for instance a mold compound. A mold compound may comprise a matrix of flowable and hardenable resin material, optionally one or more additives, and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In the context of the present application, the term “encapsulant for electronic package” may particularly denote that the encapsulant is suitable and configured for encapsulating one or more elements of an electronic package, in particular an electronic component and/or a carrier. This may require in particular a sufficient electric insulation of the encapsulant for preventing flow of electric current through the encapsulant. Furthermore, this may require a proper adhesion of the encapsulant with one or more elements of the package (in particular an electronic component and/or a carrier), which may be accomplished by an appropriate matrix material and/or one or more appropriate additives of the encapsulant.

In the context of the present application, the term “package” may particularly denote an electronic device which may comprise one or more electronic components mounted on a (in particular partially or entirely electrically conductive) carrier. Said constituents of the package may be encapsulated at least partially by an encapsulant. Optionally, one or more electrically conductive connection elements (such as metallic pillars, pumps, bond wires and/or clips) may be implemented in a package, for instance for electrically coupling and/or mechanically supporting the electronic component.

In the context of the present application, the term “organic constituent” may particularly denote a component of the encapsulant being a chemical compound that contains carbon-hydrogen bonds and/or carbon-carbon bonds and/or carbon-oxygen bonds and/or carbon-nitrogen bonds and/or carbon-sulfur bonds.

In the context of the present application, the term “inorganic constituent” may particularly denote a component of the encapsulant being a chemical compound that does not contain carbon-hydrogen bonds and/or carbon-carbon bonds and/or carbon-oxygen bonds and/or carbon-nitrogen bonds and/or carbon-sulfur bonds.

In the context of the present application, the term relative dielectric constant” may particularly denote the relative permittivity being the permittivity of a material expressed as a ratio with the electric permittivity of a vacuum. The relative dielectric constant is denoted as εᵣ. Descriptively speaking, a dielectric may be an electrically insulating material, and the dielectric constant of an insulator may describe the ability of the insulator to store electric energy in an electrical field.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and optionally an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. Also at least part of the carrier may be encapsulated by the encapsulant, together with the electronic component.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed for example in silicon technology, gallium nitride technology, silicon carbide technology, etc.

In the context of the present application, the term “chemical modification” may particularly denote a change of at least one chemical property of an organic constituent of an encapsulant having an impact on the relative dielectric constant of the organic constituent. For example, such a chemical modification may comprise the addition of a chemical group to an organic constituent, the substitution of an existing chemical group of the organic constituent by another chemical group, etc. Also a change or another modification of the backbone or a single atom of an organic constituent may be a chemical modification.

In an embodiment, the at least one organic constituent comprises a resin. For instance, a resin may be a synthetic or natural organic polymer. An example for a resin is an epoxy resin. A resin as organic constituent has turned out as an appropriate chemical compound which can be characteristically modified so as to significantly change its value of the relative dielectric constant. For example, an epoxy resin, a silicone, a bismaleimide, an imide, O-Cresol-Novolak, a multifunctional polymer, dicyclopentadienyl, biphenyl, cyanate-ester and/or a multiaromatic resin system may be used as resin.

In an embodiment, the resin comprises a thermoset resin and/or a thermoplastic resin. A thermosetting resin may be a polymer obtained by irreversibly hardening or curing a prepolymer. Curing may be induced by heat and may be promoted by pressure and/or a catalyst. Curing may result in chemical reactions that may create cross-linking between polymer chains to produce a permanently solidified polymer network. A thermoplastic resin may be a plastic polymer that becomes pliable or moldable at a certain elevated temperature and solidifies upon cooling.

In an embodiment, the at least one inorganic constituent comprises filler particles. Thus, the encapsulant may comprises inorganic (for instance ceramic) filler particles in a matrix of at least one organic constituent, such as a resin. In the context of the present application, the term “filler particles” may particularly denote a (in particular powderous or granulate-type) substance filling out interior volumes in a surrounding encapsulant medium such as a matrix. By the selection of the filler particles, the physical and/or chemical properties of the encapsulant can be adjusted. Such properties may include the coefficient of thermal expansion, the thermal conductivity, the dielectric properties, etc. The filler particles may thus be added so as to fine tune the physical, chemical, etc., properties of the encapsulant. For instance, the filler particles may increase thermal conductivity of the encapsulant so as to efficiently remove heat out of an interior of an electronic device such as a package (such heat may be generated by a semiconductor component, for instance when embodied as power semiconductor chip). It is also possible that the filler particles provide an improved dielectric decoupling between such a semiconductor component and the surrounding of the package.

In an embodiment, the filler particles comprises silicon dioxide, aluminium oxide, silicon nitride, boron nitride, magnesium oxide and/or aluminium nitride. In particular, filler particles may be selected from a group consisting of crystalline silica, fused silica, spherical silica, aluminium hydroxide, magnesium hydroxide, zirconium dioxide, calcium carbonate, calcium silicate, glass fiber and mixtures thereof. Other filler materials are however possible depending on the demands of a certain application. Filler particles (for example SiO₂, Al₂O₃, Si₃N₄, BN, AlN, etc.), for instance for improving thermal conductivity may be used as well. In particular, filler particles may be provided as nanoparticles or microparticles. Filler particles may have identical dimensions or may be provided with a distribution of particle sizes. Such a particle size distribution may be preferred since it may allow for an improved filling of gaps in an interior of the encapsulant. For instance, the shape of the filler particles may be randomly, spherical, cuboid-like, flake-like, and film-like. The filler particles can be modified, coated, and/or treated to modify its relative dielectric constant and/or to improve the adhesion and/or the chemical binding to the surrounding matrix. A coating can also change the surface energy of the fillers.

In an embodiment, the at least one organic constituent comprises at least one additive. Additives can be excipients or other material that can be added to the encapsulant in small quantities to achieve or improve certain properties. For instance, the at least one additive comprises a hardener, an adhesion promoter and/or a colorant. A hardener may promote curing or hardening of a resin of the encapsulant. An adhesion promoter may promote adhesion among the constituents of the encapsulant and/or between the constituents of the encapsulant and another structural feature of a package (such as an electronic component, a carrier, etc.). Additionally or alternatively, one or more other additives may be added.

In an embodiment, the at least one organic constituent has at least one added chemical group. The added chemical group may be selected so that, with said added chemical group, the respective organic constituent has another value of the relative dielectric constant than without the added chemical group. For instance, the value of the relative dielectric constant of the organic constituent with the added chemical group may differ from the value of the relative dielectric constant of the organic constituent without the chemical group by at least 0.5, preferably by at least 1.

In an embodiment, a difference between the relative dielectric constant of the at least one organic constituent with the at least one added chemical group and the relative dielectric constant of the at least one organic constituent without the at least one added chemical group divided by the relative dielectric constant of the at least one organic constituent with the at least one added chemical group has an absolute value of more than 0.2, preferably of more than 0.3. Correspondingly, when executing the method, a difference between the relative dielectric constant of the at least one organic constituent without the chemical modification and the relative dielectric constant of the at least one inorganic constituent divided by the relative dielectric constant of the at least one organic constituent without the chemical modification has an absolute value of more than 0.2, for instance more than 0.3. Hence, a significant change of the value of the relative dielectric constant may be achieved by such an added or a substituted chemical group. In absolute values, the difference may be at least 0.5, preferably at least 1. In this context, reference is made in particular to the examples of below described Table 1.

In an embodiment, the at least one organic constituent comprises a chemical group which has a relative dielectric constant smaller than 3 or larger than 5. For example, the at least one organic constituent without the chemical group may have a relative dielectric constant larger than 3 and smaller than 5. The below described Table 1 provides a list of examples with which the mentioned criterion may be fulfilled.

In an embodiment, the at least one organic constituent comprises a chemical group comprising a methyl group, a methoxy group, an ethoxy group, an isopropoxy group, an n-propoxy group and/or a perfluoroethoxy group. As can be taken from below described Table 1, such chemical groups may be used for adjusting the value of the relative dielectric constant over a broad range, selectively towards smaller values and towards larger values. Generally, the at least one organic constituent may comprise an alkyl, an alkoxy, an aromatic, an amino, an amido, a siloxy and/or a perfluoronated group.

In an embodiment, the difference between the relative dielectric constant of the at least one organic constituent and the relative dielectric constant of the at least one inorganic constituent divided by the relative dielectric constant of the at least one organic constituent has an absolute value of not more than 0.1, for instance of not more than 0.05. Correspondingly, the method may comprise chemically modifying the at least one organic constituent so that a difference between the relative dielectric constant of the chemically modified at least one organic constituent and the relative dielectric constant of the at least one inorganic constituent divided by the relative dielectric constant of the chemically modified at least one organic constituent has an absolute value of not more than 0.2, for instance not more than 0.1, preferably not more than 0.05. Most preferred may be an embodiment in which the difference between the relative dielectric constant of the at least one organic constituent and the relative dielectric constant of the at least one inorganic constituent is zero, or differs by not more than ±2% or even by not more than ±1%.

In an embodiment, the encapsulant is configured as a mold compound. In particular, the encapsulant may be an epoxy-based mold compound. More generally, different mold compound types may be used, such as bismaleimide mold compound, imide mold compound, etc. Molding may denote a manufacturing process of shaping liquid or pliable raw material using a rigid tool called a mold. Hence, encapsulation of one or more electronic components (such as semiconductor components) of the package may be accomplished by molding. Consequently, the encapsulant may comprise an organic curable matrix (for instance on the basis of epoxy resin) with inorganic filler particles (for fine-tuning encapsulant functions) therein. By reducing or even eliminating mismatch of the relative dielectric constant of organic and inorganic constituents of the mold compound, a further improved electric reliability of the obtained molded package may be achieved.

In an embodiment, the encapsulant is configured as a potting compound. For example, said potting compound may be embodied as a silicone gel-based compound. In particular, potting may denote a process of filling an electronic assembly with a solid or gelatinous compound, for example for high voltage assemblies. This may suppress or exclude gaseous phenomena such as corona discharge, may be done for resistance to shock and vibration, and/or may be executed for the exclusion of water, moisture, etc. When reducing or even eliminating mismatch of the relative dielectric constant of organic and inorganic constituents of the potting compound, electric reliability of the obtained encapsulated package may be further improved.

In an embodiment, the method comprises determining the chemical modification by adding or substituting a chemical group of the at least one organic constituent. By modeling, simulating and/or theoretically evaluating the impact of an added or substituted chemical group to the relative dielectric constant of the correspondingly modified organic constituent, it can be determined which chemical modification allows to change the value of the relative permittivity of the modified organic constituents so that the Fr mismatch in the encapsulant is reduced or even eliminated. Reducing or eliminating said mismatch may require increasing or decreasing the relative dielectric constant of the correspondingly modified organic constituent compared to the relative dielectric constant of the initial or non-modified organic constituent.

In an embodiment, the method comprises adding a chemical group to the at least one organic constituent or substituting a chemical group of the at least one organic constituent so that the relative dielectric constant of the at least one organic constituent with the added or substituted chemical group differs from the relative dielectric constant of the at least one inorganic constituent by a smaller absolute value than the relative dielectric constant of the at least one organic constituent without the added or substituted chemical group differs from the relative dielectric constant of the at least one inorganic constituent. To put it shortly, the modification by adding or substituting a chemical group may reduce the Fr mismatch between organic and inorganic compound of the encapsulant.

In an embodiment, the method comprises evaluating numerically the relative dielectric constant of the defined at least one organic constituent, of the defined at least one inorganic constituent, of at least one possible chemical group to be added or substituted at the at least one organic constituent and/or of the at least one organic constituent with one or more possible chemical modifications, and using results of the numerical evaluation for determining the chemical modification to be applied to the defined at least one organic constituent. For instance, an electric dipole moment can be calculated or estimated based on a molecular structure of the organic constituent. By the Debye equation, the electric dipole moment is correlated with the relative dielectric constant, which can therefore be calculated or estimated based on the dipole moment. Accordingly, the relative dielectric constant of a respective inorganic constituent of the encapsulant may be calculated or estimated. In a corresponding way, also the relative dielectric constant of a chemical group can be calculated or estimated. Additionally or alternatively, it may also be possible to calculate or estimate the relative dielectric constant of the organic constituent with added or substituted chemical group. On the basis of such a numerical analysis, it may then be possible to test which of a plurality of candidates for a chemical group would be an appropriate or the most appropriate chemical group to be added to or substituted by another chemical group of a respective constituent (in particular a respective organic constituent) of the encapsulant. Thereby, the εᵣ mismatch in the encapsulant to be designed may be reduced or even eliminated.

In an embodiment, the encapsulant (for instance a mold compound) comprises organic resin, one or more organic and/or inorganic additives (for example a hardener, a colorant such as carbon black and/or an adhesion promoter), and inorganic filler particles. For instance, the resin may be present with a weight percentage, in relation to the weight of the entire encapsulant, of not more than 20% or even of not more than 10%, the additive(s) may be present with a weight percentage, in relation to the weight of the entire encapsulant, of not more than 20% or even of not more than 10%, and the filler particles may be present with a weight percentage, in relation to the weight of the entire encapsulant, of not more than 90% (for example in a range from 60% to 90% or even in a range from 80% to 90%).

In an embodiment, the electronic component is a semiconductor power chip. Thus, the semiconductor component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the package is a power package. In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, a Thin Small Outline Package (TSOP) package, and a Quadrupole Discrete Packaging (QDPAK) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user-convenient.

In an embodiment, the package comprises a plurality of semiconductor components encapsulated by the semiconductor package encapsulant. Thus, the package may comprise one or more semiconductor components (for instance at least one passive component, such as a capacitor, and at least one active component).

As substrate or wafer forming the basis of the semiconductor component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Conventionally, electrically insulating encapsulants may suffer from a limited lifetime stability. It has been found that this shortcoming may be due to a difference in the dielectric constants between the inorganic part and the organic part of the encapsulant. Such a dielectric constant mismatch may result in a noteworthy local electric field, which may lead to overstress and material decomposition. As a consequence, the dielectric insulation property of a conventional encapsulant may be deteriorated or even lost. This may cause the risk of a reliability fail of the encapsulant or a package having an electronic component encapsulated by such an encapsulant in the field.

According to an exemplary embodiment, a (for example mold-type) encapsulant for an electronic package (for instance packaging a semiconductor die or one or more other electronic components) is provided which may overcome the above-mentioned shortcomings and may ensure an excellent electric reliability of the encapsulant and a corresponding package. Advantageously, one or more organic constituents and one or more inorganic constituents of such an encapsulant may have at least partially adapted or mutually adjusted values of the relative dielectric constant. More precisely, the organic and inorganic constituents of an encapsulant according to an exemplary embodiment may be selected (for instance by a chemical adaptation, substitution or modification, for example by correspondingly adding, removing or substituting one or more chemical groups of at least one of the constituents) to meet the criterion that a difference between the relative dielectric constant of the at least one organic constituent and the relative dielectric constant of the at least one inorganic constituent divided by the relative dielectric constant of the at least one organic constituent has an absolute value of not more than 0.2. Thus, organic and inorganic constituents of an encapsulant may be selected with mutually adapted values of their relative dielectric constant to ensure a sufficiently small εᵣ-deviation so that the electric field strength in the encapsulant may be strongly reduced in comparison with conventional approaches. This may lead to improved lifetime stability and robustness of the encapsulant material against decomposition. Hence, reliability of an encapsulated package may be improved.

In an advantageous embodiment of an encapsulant manufacturing method for adjusting matching gr-values of organic and inorganic constituents of an encapsulant, it may be defined which one or more organic constituents and which one or more inorganic constituents shall be included in an encapsulant to be created. Moreover, an evaluation may be made with chemical modification shall be applied (for instance which chemical group shall be added or substituted by another chemical group) to said one or more previously defined organic constituent. This evaluation may lead to a determination of an appropriate (for instance most appropriate) reduction of a difference between the relative dielectric constant of the at least one organic constituent and the relative dielectric constant of the at least one inorganic constituent by the evaluated chemical modification. After having identified a chemical modification fulfilling the mentioned condition concerning εᵣ mismatch reduction or even elimination, the encapsulant may be physically manufactured according to the defined at least one inorganic constituent and the at least one organic constituent under consideration of the determined chemical modification. As a result, an encapsulant may be obtained which has a proper electric reliability thanks to the εᵣ mismatch reduction or even elimination. Hence, an exemplary embodiment adjusts a tailored dielectric constant of constituents of an insulation layer to be used for encapsulating one or more electronic components. In particular, this may be accomplished by adapting of the relative dielectric constant of inorganic and organic components to a sufficiently similar or even to the same level in order to reduce or even minimize the electrical field strength of the encapsulant.

Such embodiments may be based on the finding that the one or more organic components or constituents of an encapsulant may be the weak point in an insulation system. With the adapting of the dielectric constant of inorganic and organic components or constituents in the insulation system or encapsulant to the same or a sufficiently similar level, the local electrical field can be reduced or even minimized in particular in the organic component. Thereby, the lifetime stability of the encapsulant can be increased because local material decomposition can be avoided. Furthermore, a risk of a reliability fail in field can be reduced or even minimized.

For instance, the encapsulant may be embodied as a mold compound. An example for an appropriate system for dielectric property adaption is an epoxy polymer system like biphenyl and multiaromatic resin types. However, exemplary embodiments may make an adaptation for a hardener structure as well. For instance, a chemical modification by adding or substituting a chemical group according to an exemplary embodiment may vary a CH₃ group for instance by substituting it by —N(CₓH_{y})₂, —OH, —NH(CₓH_{y}), —SH, —COOCH, —CₓH_{y}O and/or —CO—CH₃. In particular, a change of dielectric properties by changing the molecular structure to more or less polar groups may be an advantageous embodiment.

According to an exemplary embodiment, the dielectric properties of at least one constituent of a mold compound or another encapsulant may be configured, adapted or changed so that the values of the relative dielectric constant of organic and inorganic constituents of the encapsulant may be rendered identical or sufficiently similar so as to differ from each other by not more than ±20%. In this context, it turned out to be particularly appropriate to adapt the value of the relative dielectric constant of the organic constituent(s), which may be made in a simple and flexible way by correspondingly selecting, adding and/or substituting one or more chemical groups of such an organic constituent. For example, it may be possible to change the molecular structure of an organic constituent to modify its polarity. In one example, this may be done by substituting a CH₃-group by an n-propoxy-group. For instance, a residue of a resin may be substituted by another residue. To put it shortly, an adaptation or mutual matching of the value of the relative dielectric constant in a mold compound may be done between inorganic fillers and an organic polymer. If inorganic and organic constituents of an encapsulant differ from each other concerning the value of the relative dielectric constant excessively, inappropriate electric conditions may occur within the encapsulant, which may lead to breakthrough and/or other undesired phenomena.

However, additionally or alternatively, also an inorganic constituent of the encapsulant may be adapted or modified for adjusting its relative dielectric constant, for instance by a corresponding coating.

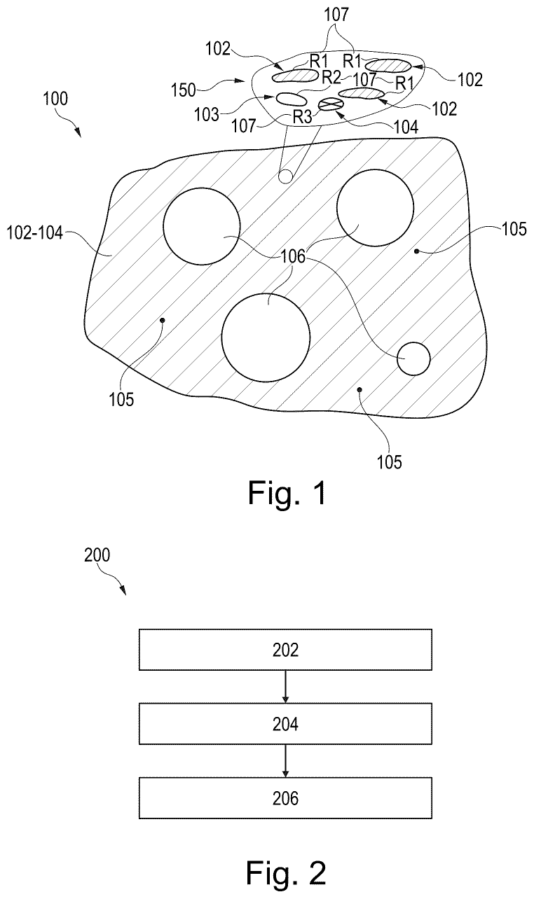

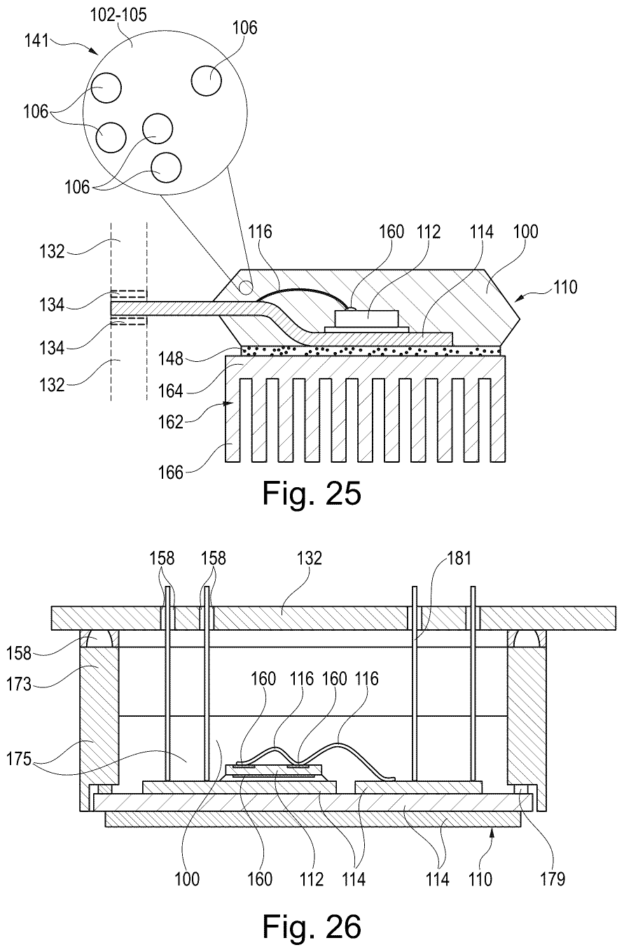

FIG. 1 illustrates an encapsulant 100 according to an exemplary embodiment. The schematically illustrated encapsulant 100 is configured for encapsulating an electronic package 110, such as the one shown in FIG. 25 or FIG. 26.

As shown, the encapsulant 100 comprises an electrically insulating matrix material which may be formed of a plurality of organic constituents 102-105, i.e. constituents made of an organic material.

For a mold compound-type encapsulant 100 as used for the package 110 of FIG. 25, the matrix material may comprise an epoxy resin as a resin 102. For a potting-type encapsulant 100 as used for the package 110 of FIG. 26, the matrix material may comprise a resin 102 which may be embodied as silicone resin.

Apart from this, one or a plurality of additives 103-105 may be added to the encapsulant 100 for further adjusting its physical properties and for providing a dedicated functionality. Such additives may comprise for example a hardener 103, an adhesion promoter 104, and a colorant 105. Additionally or alternatively, at least one further additive may be provided, such as a voltage stabilizer, an antioxidant, an ultraviolet (UV) absorber, low stress additives, etc. (not shown).

Moreover, the encapsulant 100 may comprise ceramic filler particles as inorganic constituent 106, i.e. a further constituent of the encapsulant 100 made of an inorganic material. Said filler particles may be configured for fine-tuning the physical properties of the encapsulant 100. For example, the filler particles may be made of aluminum nitride for enhancing thermal conductivity.

Hence, the described encapsulant 100 comprises a plurality of organic constituents 102-105 and one inorganic constituent 106. Other smaller or larger numbers of organic and/or inorganic constituents of the encapsulant 100 are however possible.

Advantageously, a ratio of a difference between a relative dielectric constant εᵣ (for instance an average relative dielectric constant) of one, some or all of the organic constituents 102-105 on the one hand and the relative dielectric constant εᵣ of the inorganic constituent 106 on the other hand, divided by the (for instance averaged) relative dielectric constant ϵᵣ of said one, some or all of the organic constituents 102-105 may have an absolute value of not more than 0.2. For all embodiments, an average relative dielectric constant Fr of plural organic constituents 102-105 may be calculated as the sum, over all organic constituents 102-105, of the products of the relative dielectric constant Fr of the respective individual organic constituent 102-105 multiplied by the weight percentage of said respective organic constituent 102-105. Said individual weight percentage may be the weight of the respective individual organic constituent 102-105 of the encapsulant 100 divided by the overall weight of all organic constituents 102-105 of the encapsulant 100. For all embodiments, an average relative dielectric constant εᵣ of plural inorganic constituents 106 (if present) may be calculated as the sum, over all inorganic constituents 106, of the products of the relative dielectric constant εᵣ of the respective individual inorganic constituent 106 multiplied by the weight percentage of said respective inorganic constituent 106. Said individual weight percentage may be the weight of the respective individual inorganic constituent 106 of the encapsulant 100 divided by the overall weight of all inorganic constituents 106 of the encapsulant 100. The described “not more than 0.2” criterion may be applied on the basis of such an average value of the relative dielectric constant εᵣ averaged over plural organic constituents 102-105 and/or over plural inorganic constituents 106.

Now referring to a detail 150 of FIG. 1, the used resin 102, the used hardener 103 and/or the used adhesion promoter 104 can be provided with a respectively added chemical group 107. Said added chemical group 107 is denoted in FIG. 1 as a residue R1 for the resin 102, as a residue R2 for the hardener 103, and as a residue R3 for the adhesion promoter 104. For instance, the respective chemical group 107 forming residue R1, R2 and R3, respectively, may comprise for example a methyl group, a methoxy group, an ethoxy group, an isopropoxy group, an n-propoxy group and/or a perfluoroethoxy group. It has been found that by adding such a chemical group 107, the relative dielectric constant Fr of the respective organic constituent 102-105 can be influenced significantly (see Table 1 below). By a corresponding selection of such one or more chemical groups 107 of one or more of said organic constituents 102-105, a mismatch between the (for instance averaged) relative dielectric constant εᵣ of the organic constituents 102-105 on the one hand and the relative dielectric constant εᵣ of the inorganic constituent 106 can be reduced or even eliminated. In particular, a difference between the (for instance averaged, weighted over the individual organic constituents 102-105) relative dielectric constant of the at least one organic constituent 102-105 with the at least one added chemical group 107 and the (for instance averaged, weighted over the individual organic constituents 102-105) relative dielectric constant εᵣ of the at least one organic constituent 102-105 without the one or more added chemical groups 107 divided by the (for instance averaged, weighted over the individual organic constituents 102-105) relative dielectric constant Fr of the organic constituent(s) 102-105 with the at least one added chemical group 107 has an absolute value of more than 0.2 (for example more than 0.3). By the added chemical group(s) 107, said absolute value may be reduced from above 0.2 (for example from above 0.3) to below 0.2 (for example below 0.1).

By the described chemical adaptation of the relative dielectric constant of inorganic component 106 and organic components 102-105 of the encapsulant 100, the electric field strength may be made smaller. This may allow to increase lifetime stability of the encapsulant 100. As a result, material decomposition of the encapsulant 100 can be suppressed. When using such an encapsulant 100 for encapsulating, an electronic package 110 with high electric reliability may be obtained thanks to the matching or adapted εᵣ-values of its organic constituents 102-105 and its inorganic constituent 106.

FIG. 2 illustrates a flowchart 200 of a method of manufacturing an encapsulant 100 for an electronic package 110 according to an exemplary embodiment. The reference signs used for the following description of said manufacturing method relate to the embodiments of FIG. 1 and FIG. 25.

Referring to a block 202, the method comprises defining at least one organic constituent 102-105 and at least one inorganic constituent 106 of the encapsulant 100.

Referring to a block 204, the method furthermore comprises determining a chemical modification to be applied to the defined at least one organic constituent 102-105 to reduce a difference between the relative dielectric constant of the at least one organic constituent 102-105 and the relative dielectric constant of the at least one inorganic constituent 106 by the chemical modification.

Referring to a block 206, the method furthermore comprises manufacturing the encapsulant 100 based on the defined at least one inorganic constituent 106 and based on the at least one organic constituent 102-105 with the determined chemical modification.

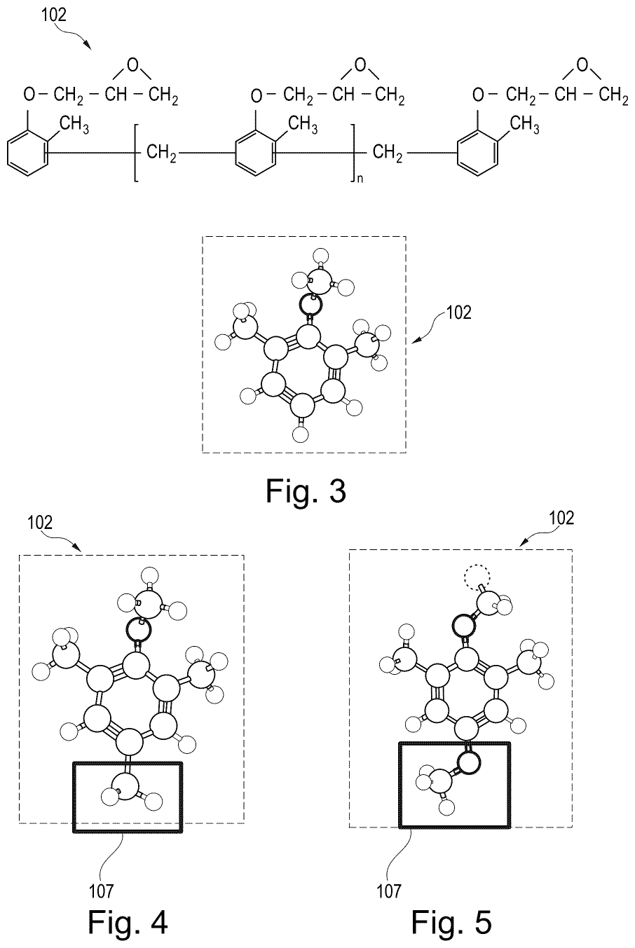

FIG. 3 to FIG. 21 show chemical compounds which may be used for an encapsulant 100 of exemplary embodiments.

As a basis for the following description, values of the relative dielectric constant Fr for different chemical groups 107 or residues of one or more organic constituents 102-105 (see Table 1) and of different filler particles as one or more inorganic constituents 106 (see Table 2) will be summarized.

TABLE 1
relative dielectric constant εᵣ for different
chemical groups or residues of resin

| Residue/chemical group | Dipole moment (estimated) | εᵣ (estimated) |
|---|---|---|
| H- (reference) | 2.408 | 3.21 |
| Methyl- | 2.453 | 3.36 |
| Methoxy- | 2.896 | 5.76 |
| Ethoxy- | 2.804 | 5.06 |
| n-propoxy | 3.190 | 9.73 |
| Isopropoxy- | 2.837 | 5.29 |
| perfluoroethoxy | 2.221 | 2.70 |

TABLE 2
relative dielectric constant εᵣ of different inorganic filler particles

| Filler particle material | εᵣ |
|---|---|
| Silicon dioxide | 3.74 |
| Aluminum oxide | 9 |
| Silicon nitride | 8.2 |
| Boron nitride | 4 |
| Aluminum nitride | 9 |

First referring to Table 1, the given values may be evaluated or determined based on the Debye equation correlating electric dipole moment and relative dielectric constant εᵣ. In the Debye equation:

$${P}_{m} = \frac{{ε}_{r} - 1}{{ε}_{r} + 2} \cdot \frac{M}{ρ} = \frac{{N}_{A}}{3 {ε}_{0}} ( α + \frac{{μ}^{2}}{3 {k}_{B} T} )$$

Pₘ is the molar polarization, M is the molar mass, ρ is the density, N_{A} is the Avogadro constant, ε₀ is the electric field constant, k_{B} is the Boltzmann constant, T is the temperature, μ² indicates the orientation polarization, and a the shifting polarization.

FIG. 3 shows a structural formula and a three-dimensional molecular structure of a base resin which may be used for instance as resin 102 of encapsulant 100. Said base resin has the chemical designation polyglycidyl ether of ortho cresol novolac (chemical abstract service registry number: 29690-82-2). Referring to FIG. 3, a polymer linker is simplified as methyl group and treated as symmetrical. An epoxy function is simplified as methoxy group. The Avogadro forcefield geometry may be optimized with multiple starting geometries.

Based on the Debye equation and the information about the base resin according to FIG. 3, the dipole moment and the relative dielectric constant εᵣ of the base resin may be estimated or determined. The results for this reference are indicated in the second row of Table 1.

When substituting the residue H—of said base resin by other residues according to Table 1, the dipole moment and the relative dielectric constant εᵣ of the base resin with substituted residue or chemical group 107 may be estimated or determined. The results are shown in the subsequent rows of Table 1.

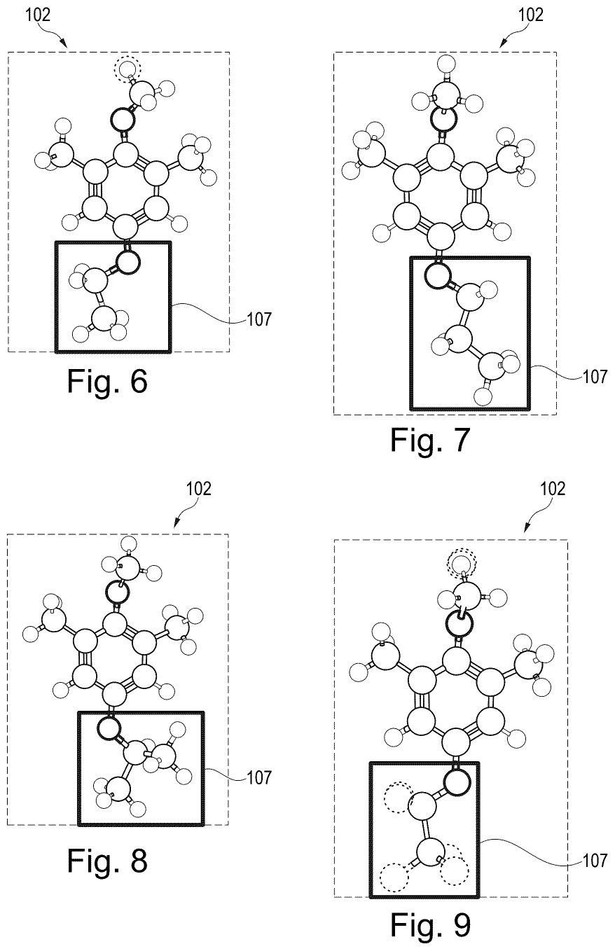

More specifically, the three-dimensional chemical structure of the base resin with a substituted chemical group 107 in form of methyl is illustrated in FIG. 4 and the third row of Table 1. The three-dimensional chemical structure of the base resin with a substituted chemical group 107 in form of methoxy is illustrated in FIG. 5 and the fourth row of Table 1. The three-dimensional chemical structure of the base resin with a substituted chemical group 107 in form of ethoxy is illustrated in FIG. 6 and the fifth row of Table 1. The three-dimensional chemical structure of the base resin with a substituted chemical group 107 in form of n-propoxy is illustrated in FIG. 7 and the sixth row of Table 1. The three-dimensional chemical structure of the base resin with a substituted chemical group 107 in form of isopropoxy is illustrated in FIG. 8 and the seventh row of Table 1. The three-dimensional chemical structure of the base resin with a substituted chemical group 107 in form of perfluoroethoxy is illustrated in FIG. 9 and the eighth row of Table 1.

As can be taken from Table 1, the relative dielectric constant εᵣ of the organic base resin with substituted residue or chemical group 107 can be changed over a broad range from initially 3.21 to values in a range from 2.70-9.73. With other chemical groups 107, said range may be further refined or even extended.

Now referring to Table 2, inorganic filler particles, depending on the used material, may have a value of the relative dielectric constant εᵣ differing significantly from that of the initial base resin (3.21), in the case of the shown examples in a range from 3.74 to 9. With other inorganic filler materials, said range may be further refined or even extended.

As can be taken from Table 1 and Table 2, a significant mismatch between the initial organic resin 102 and the inorganic filler particles, as inorganic constituent 106, may occur. The same is true for other organic constituents 103-105 in comparison with the inorganic constituent 106. This may lead to undesired properties of the encapsulant 100, in particular to a reduction of the dielectric reliability of the encapsulant 100.

However, when executing appropriate substitutions of a chemical group 107 of the resin 102 according to Table 1, an Fr mismatch with the inorganic constituent 106 may be reduced or even eliminated. The same is true, mutatis mutandis, with the other organic constituents 103-105.

Thus, it may be possible to determine a chemical modification by adding or substituting one or more chemical groups 107 of at least one organic constituent 102-105. In particular, adding or substituting one or more chemical groups 107 of at least one organic constituent 102-105 may be made so that the relative dielectric constant of the at least one organic constituent 102-105 with added or substituted chemical group(s) 107 differs from the relative dielectric constant of the at least one inorganic constituent 106 less than the relative dielectric constant of the at least one organic constituent 102-105 without added or substituted chemical group(s) 107 differs from the relative dielectric constant of the at least one inorganic constituent 106. The chemical modification may be reduced so that a difference between the relative dielectric constant of the chemically modified at least one organic constituent 102-105 and the relative dielectric constant of the at least one inorganic constituent 106 divided by the relative dielectric constant of the chemically modified at least one organic constituent 102-105 has an absolute value of not more than 0.2, for instance not more than 0.1. Before such a modification, a difference between the relative dielectric constant of the at least one organic constituent 102-105 without the chemical modification and the relative dielectric constant of the at least one inorganic constituent 106 divided by the relative dielectric constant of the at least one organic constituent 102-105 without the chemical modification may have an absolute value of more than 0.2, for instance more than 0.3.

As described referring to FIG. 3 to FIG. 9, it may be possible to evaluate numerically the relative dielectric constant of a defined at least one organic constituent 102-105, of a defined at least one inorganic constituent 106, of at least one possible chemical group 107 to be added or substituted at the at least one organic constituent 102-105 and/or of the at least one organic constituent 102-105 with one or more possible chemical modifications. Using results of the numerical evaluation, it may then be possible to determine the chemical modification to be applied to the defined at least one organic constituent 102-105.

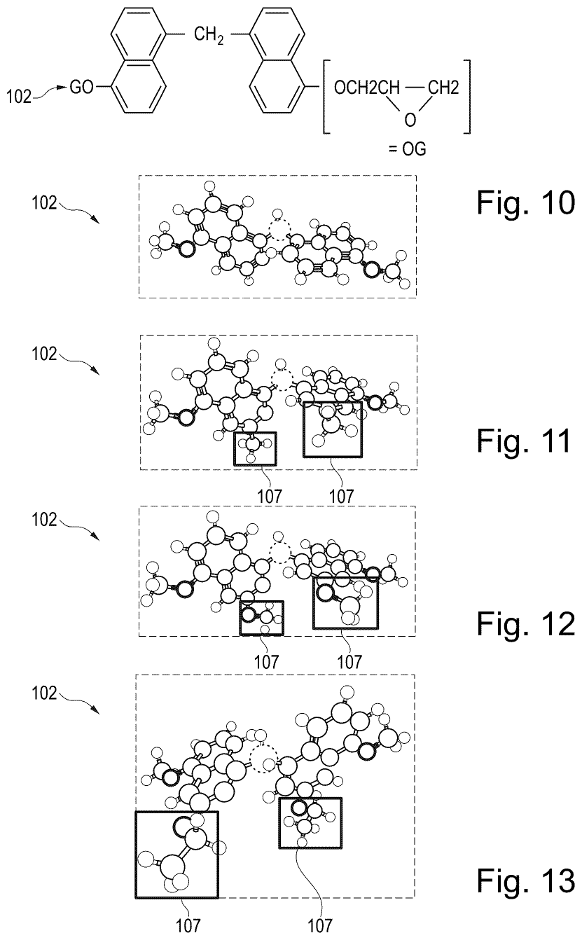

A further example with another base resin, illustrated in FIG. 10, leads to corresponding results. Starting from an estimated dipole moment of 3.182 of said base resin without residue or chemical group 107, the following additions of a chemical group 107 lead to significant changes of the estimated dipole moment: According to FIG. 11, a chemical group 107 in form of methyl has been added to the base resin of FIG. 10, which leads to an estimated dipole moment of 2.968. According to FIG. 12, a chemical group 107 in form of methoxy has been added to the base resin of FIG. 10, which leads to an estimated dipole moment of 5.694. According to FIG. 13, a chemical group 107 in form of ethoxy has been added to the base resin of FIG. 10, which leads to an estimated dipole moment of 6.967.

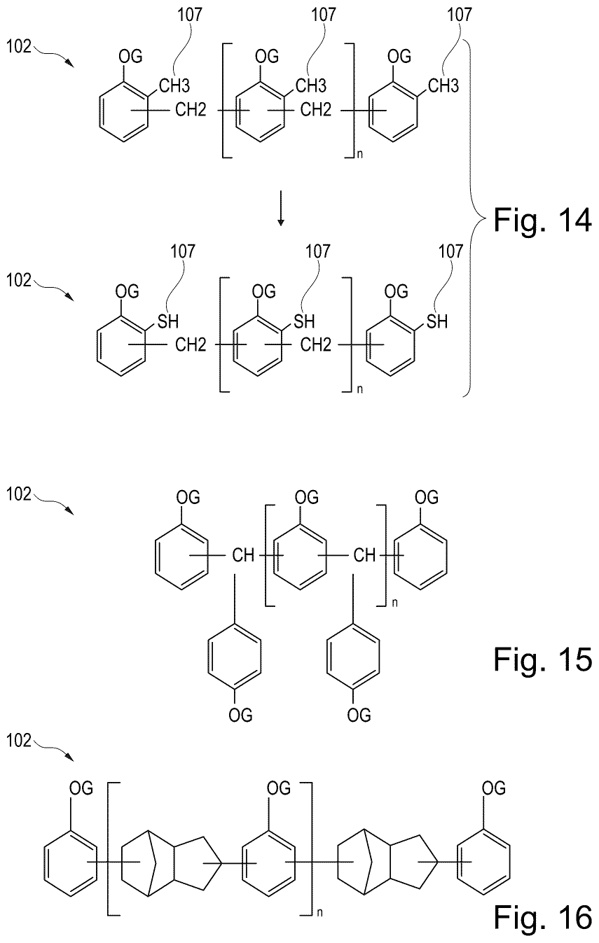

FIG. 14 shows another example of a residue substitution, in which a base resin (o-cresol-novolak) has been modified by substituting a chemical group 107 in form of —CH₃ by another chemical group 107 in form of —SH.

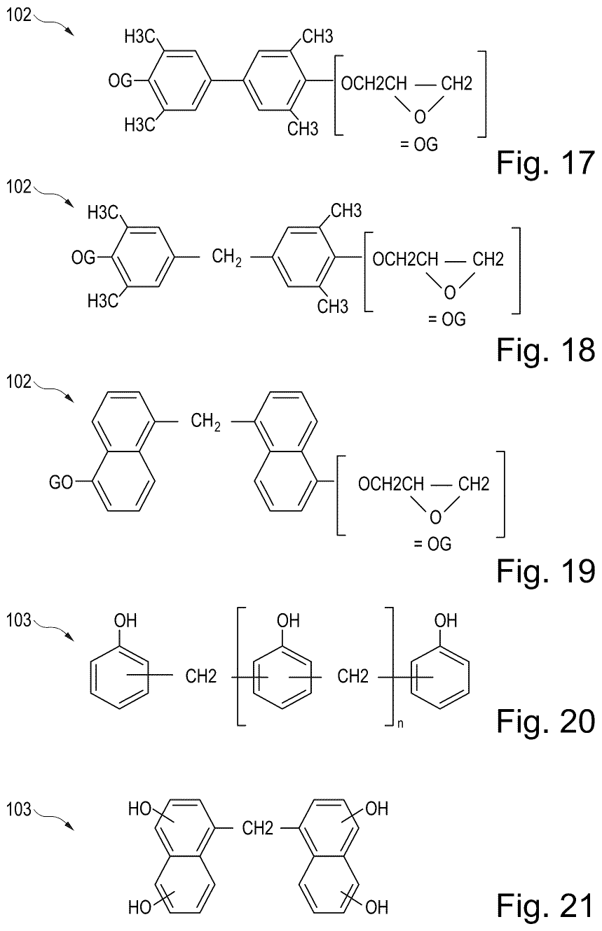

FIG. 15 to FIG. 19 shows other base resins for a polymer system of a mold compound-type encapsulant 100. The resin 102 shown in FIG. 15 is a multifunctional resin leading to a high glass temperature and low warpage. The resin 102 shown in FIG. 16 is a resin 102 based on dicyclopentadienyl, which may have the advantage of less water uptake. The resin 102 shown in FIG. 17 is a biphenyl, which may have the advantage of less water uptake and high filler content. The resins 102 shown in FIG. 18 and FIG. 19 are of a multiaromic resin system, which may have the advantage of less water uptake and higher rigidity, since being less crystalline.

FIG. 20 and FIG. 21 show examples for hardeners 103, which can also be subjected to addition or modification of one or more chemical groups 107. Since such hardeners 103 have a similar chemistry like resins 102, also their properties can be changed through a combination of different systems for adjusting the value of the relative dielectric constant Pr.

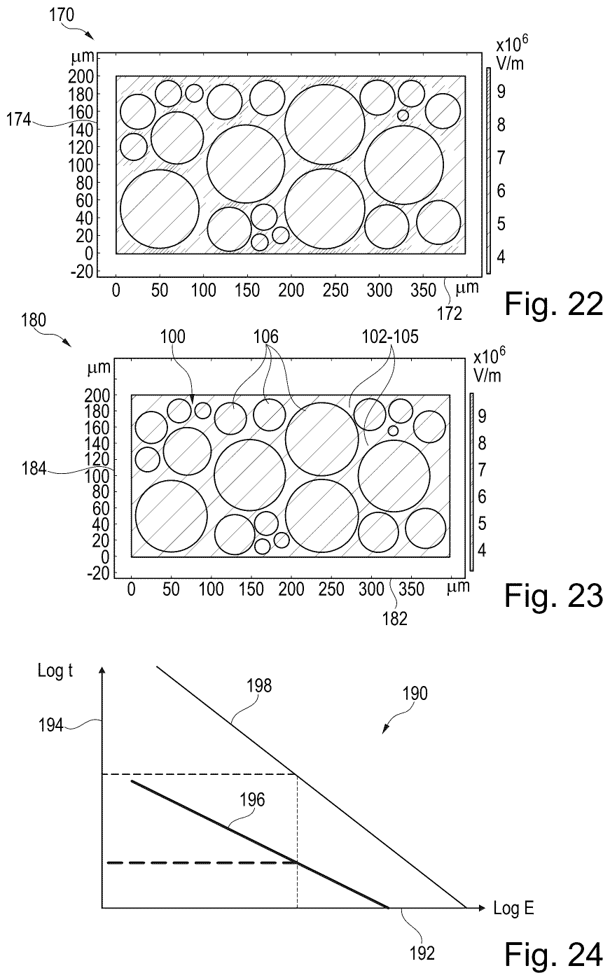

FIG. 22 to FIG. 24 show diagrams 170, 180, 190 used for explaining effects of exemplary embodiments compared to conventional approaches. FIG. 22 to FIG. 24 relate to a steady state electrical field simulation (cross-section of organic insulation layer). FIG. 22 to FIG. 24 indicate that, by adjusting the dielectric constants of an organic part and an inorganic part of the insulation system or encapsulant 100, the lifetime stability may be increased. This may reduce the risk of reliability fail in field.

Referring to FIG. 22, a diagram 170 is shown having an abscissa 172 along which a dimension in micrometres is plotted. Along an ordinate 174, a further dimension in micrometres is plotted. FIG. 22 relates to the scenario that the relative dielectric constant of the inorganic constituent 106 is larger than the relative dielectric constant of the organic constituent(s) 102-105 of the encapsulant 100. With a color code, the electric field in the encapsulant 100 is plotted. Regions of remarkably high electric field can be seen.

Referring to FIG. 23, a diagram 180 is shown having an abscissa 182 along which a dimension in micrometres is plotted. Along an ordinate 184, a further dimension in micrometres is plotted. FIG. 23 relates to the scenario that the relative dielectric constant of the inorganic constituent 106 is the same as the relative dielectric constant of the organic constituent(s) 102-105 of the encapsulant 100. With a color code, the electric field in the encapsulant 100 is plotted. As seen, the electric fields is small and homogeneous.

Referring to FIG. 24, a diagram 190 is shown having an abscissa 192 along which the logarithm of the electric field is plotted. Along an ordinate 184, the logarithm of the time is plotted. A first curve 196 relates to the scenario of FIG. 22, whereas a second curve 198 relates the scenario of FIG. 23.

As can be taken from FIG. 24, the electric field stability is significantly better according to FIG. 23, relating to an exemplary embodiment, compared with a conventional encapsulant according to FIG. 22.

FIG. 25 illustrates a cross-sectional view of a molded package 110 according to an exemplary embodiment.

The semiconductor package 110 is mounted on a mounting structure 132, here embodied as printed circuit board.

The mounting structure 132 comprises an electric contact 134 embodied as a plating in a through hole of the mounting structure 132. When the semiconductor package 110 is mounted on the mounting structure 132, a semiconductor component 112 of the semiconductor package 110 is electrically connected to the electric contact 134 via an electrically conductive carrier 114, here embodied as a leadframe made of copper.

The semiconductor package 110 thus comprises the electrically conductive carrier 114, the semiconductor component 112 (which is here embodied as a power semiconductor chip) mounted on the carrier 114, and an encapsulant 100 encapsulating part of the carrier 114 and the semiconductor component 112.

As can be taken from FIG. 25, a pad 160 on an upper main surface of the semiconductor component 112 is electrically coupled to the carrier 114 via a bond wire as electrically conductive connection element 116. Alternatively, a clip may be used as electrically conductive connection element 116 (not shown).

In particular, the carrier 114 may comprise different leads, that are going out of the encapsulant 110 of the package 110. The backside of the semiconductor component 112 (such as a die) is connected to one part of the carrier 114, while the electrically conductive connection element 116 (such as a bond wire) is not connected to the same lead. Instead, each lead may be separately connected to the carrier 114 at different contact holes.

During operation of the power semiconductor package 110, the power semiconductor chip in form of the semiconductor component 112 generates a considerable amount of heat. At the same time, it shall be ensured that any undesired current flow between a bottom surface of the semiconductor package 110 and an environment is reliably avoided.

For ensuring electrical insulation of the semiconductor component 112 and removing heat from an interior of the semiconductor component 112 towards an environment, an electrically insulating and thermally conductive interface structure 148 may be provided which covers an exposed surface portion of the carrier 114 and a connected surface portion of the encapsulant 100 at the bottom of the semiconductor package 110. The electrically insulating property of the interface structure 148 prevents undesired current flow even in the presence of high voltages between an interior and an exterior of the semiconductor package 110. The thermally conductive property of the interface structure 148 promotes a removal of heat from the semiconductor component 112, via the electrically conductive carrier 114 (for instance of thermally conductive copper), through the interface structure 148 and towards a heat dissipation body 162. The heat dissipation body 162, which may be made of a highly thermally conductive material such as copper or aluminum, has a base body 164 directly connected to the interface structure 148 and has a plurality of cooling fins 166 extending from the base body 164 and in parallel to one another so as to remove the heat towards the environment.

Construction and function of encapsulant 100 can be for instance as illustrated in and described referring to FIG. 1, see detail 141 of FIG. 25. The encapsulant 100 of FIG. 25 is a mold compound-type composite.

The illustrated semiconductor package encapsulant 100 encapsulates the semiconductor component 112 with its metallic pad 160, leadframe-type metallic chip carrier 114, and bond wire-type electrically conductive connection element 116 partially or entirely. Organic constituents 102-105 promote the dielectric encapsulating function of encapsulant 100. Filler particles, as inorganic constituent 106, of the semiconductor package encapsulant 100 may enhance thermal conductivity and may be made for instance of aluminum oxide and/or boron nitride.

FIG. 26 illustrates a cross-sectional view of a semiconductor package 110 with a semiconductor component 112 encapsulated by potting according to another exemplary embodiment. Thus, FIG. 26 illustrates a semiconductor package encapsulant 100 embodied as potting compound. The semiconductor package 110 of FIG. 26 can be a power package.

The shown semiconductor package 110 is mounted with a mounting structure 132 being embodied as printed circuit board (PCB). Semiconductor package 110 is mounted at its mounting interface on the mounting structure 132 with a sealing 158 in between. Preferably, the gas flow-inhibiting sealing 158 may establish a gas flow-tight connection between semiconductor package 110 and mounting structure 132.

The semiconductor package 110 comprises a semiconductor component 112, such as a power semiconductor chip, for instance comprising a field effect transistor (FET). Semiconductor component 112 has metallic pads 160.

An enclosure 175 encloses the semiconductor component 112 and defines a module interface at which the semiconductor package 110 is to be mounted on the mounting structure 132. In the shown embodiment, the enclosure 175 is composed of two parts. A first or interior part of the enclosure 175 is embodied as a soft encapsulant 100 (for instance made of a silicone gel and comprising inorganic filler particles) which directly encapsulates the semiconductor component 112 with physical contact, for instance is applied by potting. A second or exterior part of the enclosure 175 is embodied as a rigid casing or housing 173 which may be made of plastic and accommodates the semiconductor component 112 and the soft encapsulant 100.

Furthermore, vertically extending electrically conductive needles 181 may be provided which electrically couple the semiconductor component 112 and the carrier 114 with an exterior of the semiconductor package 110, more precisely with the mounting structure 132. The needles 181 may also extend through the mounting structure 132. More precisely, bottom ends (according to FIG. 26) of the needles 181 may be connected at an upper main surface of the carrier 114. Furthermore, top ends (according to FIG. 26) of the needles 181 may be guided through the mounting structure 132 and may even protrude beyond the upper side of the mounting structure 132.

As shown as well in FIG. 26, the semiconductor package 110 comprises carrier 114 carrying the semiconductor component 112. The semiconductor component 112 may be soldered on the carrier 114. In the shown embodiment, the carrier 114 comprises a central thermally conductive and electrically insulating plate (for instance made of a ceramic) covered on both opposing main surfaces thereof with a respective electrically conductive layer (such as a continuous or patterned copper or aluminium layer). For instance, the carrier 114 may be a Direct Copper Bonding (DCB) substrate or a Direct Aluminium Bonding (DAB) substrate. It is also possible to embody the carrier 114 as Active Metal Brazing (AMB) substrate. The semiconductor component 112 is mounted on the top-sided electrically conductive layer. The bottom-sided electrically conductive layer may be connected to a heat sink (not shown) for promoting heat removal out of the semiconductor package 110 during operation thereof.

Thus, the outer layer of the carrier 114 is configured for mounting a heat sink (not shown) thereon in order to efficiently remove heat out of the semiconductor package 110, which is generated by semiconductor component 112 mounted on the interior layer of the carrier 114. Said semiconductor component 112 may, for instance, be a power semiconductor chip. Electric connection of the semiconductor component 112 can be accomplished by the carrier 114 (in particular by the inner electrically conductive layer thereof) and by electrically conductive connection elements 116 connecting the carrier 114 with the pads 160 on an upper main surface of the semiconductor component 112. Said electrically conductive connection elements 116 are here embodied as bond wires, but may alternatively be bond ribbons or clips.

As shown as well, the semiconductor component 112 mounted on the carrier 114 is enclosed within the enclosure 175, which is composed of soft encapsulant 100 and wall of housing 173.

The semiconductor package 110 can further comprise a further gas flow-inhibiting sealing 179 between the carrier 114 and the housing 173 of the enclosure 175.

The electrically conductive needles 181 extend from the carrier 114 through the encapsulant 100 and through sealing 158 at the module interface at which the semiconductor package 110 faces mounting structure 132. For instance, the semiconductor package 110 and the mounting structure 132 may be connected by screwing, soldering, sintering, gluing and/or mechanically pressing.

By embodying the potting-type encapsulant 100 in a corresponding way as described above referring to FIG. 1 or FIG. 25 (however preferably based on silicone gel as matrix, whereas also epoxy resin is possible), a pronounced and defined colouring as well as a high electric reliability may be achieved.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An encapsulant for an electronic package, wherein the encapsulant comprises:
at least one organic constituent; and
at least one inorganic constituent,
wherein a difference between the relative dielectric constant of the at least one organic constituent and the relative dielectric constant of the at least one inorganic constituent divided by the relative dielectric constant of the at least one organic constituent has an absolute value of not more than 0.2.

2. The encapsulant according to claim 1, wherein the at least one organic constituent comprises a resin.

3. The encapsulant according to claim 2, wherein the resin comprises a thermoset resin and/or a thermoplastic resin.

4. The encapsulant according to claim 1, wherein the at least one inorganic constituent is implemented as filler particles.

5. The encapsulant according to claim 4, wherein the filler particles comprise silicon dioxide, aluminium oxide, silicon nitride, boron nitride, magnesium oxide or aluminium nitride.

6. The encapsulant according to claim 1, wherein the at least one organic constituent comprises at least one additive.

7. The encapsulant according to claim 6, wherein the at least one additive comprises a hardener, an adhesion promoter or a colorant.

8. The encapsulant according to claim 1,
wherein the at least one organic constituent has at least one added chemical group; and
wherein a difference between the relative dielectric constant of the at least one organic constituent with the at least one added chemical group and the relative dielectric constant of the at least one organic constituent without the at least one added chemical group divided by the relative dielectric constant of the at least one organic constituent with the at least one added chemical group has an absolute value of more than 0.2.

9. The encapsulant according to claim 1, wherein the at least one organic constituent comprises a chemical group which has a relative dielectric constant smaller than 3 or larger than 5, wherein for example the at least one organic constituent without the chemical group has a relative dielectric constant larger than 3 and smaller than 5.

10. The encapsulant according to claim 1, wherein the at least one organic constituent comprises a chemical group comprising a methyl group, a methoxy group, an ethoxy group, an isopropoxy group, an n-propoxy group, a perfluoroethoxy group, an alkyl group, an alkoxy group, an aromatic group, an amino group, an amido group, a siloxy group or a perfluoronated group.

11. The encapsulant according to claim 1, wherein the difference between the relative dielectric constant of the at least one organic constituent and the relative dielectric constant of the at least one inorganic constituent divided by the relative dielectric constant of the at least one organic constituent has an absolute value of not more than 0.1, for instance of not more than 0.05.

12. The encapsulant according to claim 1, comprising one of the following features:
configured as a mold compound;
configured as a potting compound.

13. A package, comprising:
a carrier;
an electronic component mounted on the carrier; and
an encapsulant according to claim 1 at least partially encapsulating the electronic component and the carrier.

14. The package according to claim 13, wherein the package is a power package.

15. A method of manufacturing an encapsulant for an electronic package, wherein the method comprises:
defining at least one organic constituent and at least one inorganic constituent of the encapsulant;
determining a chemical modification to be applied to the defined at least one organic constituent to reduce a difference between the relative dielectric constant of the at least one organic constituent and the relative dielectric constant of the at least one inorganic constituent by the chemical modification; and
manufacturing the encapsulant based on the defined at least one inorganic constituent and based on the at least one organic constituent with the determined chemical modification.

16. The method according to claim 15, wherein the method comprises determining the chemical modification by adding or substituting a chemical group of the at least one organic constituent.

17. The method according to claim 15, wherein the method comprises adding a chemical group to the at least one organic constituent or substituting a chemical group of the at least one organic constituent so that the relative dielectric constant of the at least one organic constituent with the added or substituted chemical group differs from the relative dielectric constant of the at least one inorganic constituent by a smaller absolute value than the relative dielectric constant of the at least one organic constituent without the added or substituted chemical group differs from the relative dielectric constant of the at least one inorganic constituent.

18. The method according to claim 15, wherein the method comprises chemically modifying the at least one organic constituent so that a difference between the relative dielectric constant of the chemically modified at least one organic constituent and the relative dielectric constant of the at least one inorganic constituent divided by the relative dielectric constant of the chemically modified at least one organic constituent has an absolute value of not more than 0.2, for instance not more than 0.1, preferably not more than 0.05.

19. The method according to claim 18, wherein a difference between the relative dielectric constant of the at least one organic constituent without the chemical modification and the relative dielectric constant of the at least one inorganic constituent divided by the relative dielectric constant of the at least one organic constituent without the chemical modification has an absolute value of more than 0.2, for instance more than 0.3.

20. The method according to claim 15, wherein the method comprises
evaluating numerically the relative dielectric constant of the defined at least one organic constituent, of the defined at least one inorganic constituent, of at least one possible chemical group to be added or substituted at the at least one organic constituent and/or of the at least one organic constituent with one or more possible chemical modifications; and
using results of the numerical evaluation for determining the chemical modification to be applied to the defined at least one organic constituent to reduce said difference.
